(19) United States
(12) Patent Application Publication
(10) Pub. No.: US 2026/0215232 A1
(43) Pub. Date: Jul. 23, 2026

(54) SUBSTRATE TREATING METHOD AND SUBSTRATE TREATING APPARATUS

(71) Applicant: SCREEN Holdings Co., Ltd., Kyoto (JP)

(72) Inventors: Yasuharu MIYAMOTO, Kyoto (JP); Yukifumi YOSHIDA, Kyoto (JP)

(21) Appl. No.: 19/139,863

(22) PCT Filed: Dec. 12, 2023
(86) PCT No.: PCT/JP2023/044464

§ 371 Date: Jun. 16, 2025

(30) Foreign Application Priority Data
Dec. 21, 2022 (JP) 2022-204443

(51) Int. Cl. H10P 76/20; G03F 1/60; G03F 7/16

(52) U.S. Cl. CPC H10P 76/20; G03F 1/60; G03F 7/165

(57) ABSTRACT

Provided are a substrate treating method and a substrate treating apparatus capable of efficiently forming a self-assembled monolayer excellent in denseness and protection performance on a substrate surface in a short time by suppressing or reducing occurrence of film defects. A substrate treating method of the present invention includes: a first contact step of bringing a first treating liquid containing SAM molecules into contact with a surface Wf of a substrate W to chemically adsorb the SAM molecules; a removal step of removing the SAM molecules that are not chemically adsorbed from the surface Wf of the substrate W; a surface modification step of performing surface modification on a region where the SAM molecule does not exist on the surface Wf after the removal step to a region where chemical adsorption of the SAM molecules is possible; and a second contact step of bringing a second treating liquid containing the SAM molecules and having the same type as or different type from the first treating liquid into contact with the region to which the surface modification has been performed to chemically adsorb the SAM molecules.

### TECHNICAL FIELD

The present invention relates to a substrate treating method and a substrate treating apparatus capable of efficiently forming a self-assembled monolayer excellent in denseness and protection performance in a short time.

### BACKGROUND ART

In the manufacture of a semiconductor device, a photolithography technique is widely used as a technique for selectively forming a film in a specific surface region of a substrate. For example, an insulating film is formed after underlayer wiring is formed, a dual damascene structure having a trench and a via hole is formed by photolithography and etching, and a conductive film of such as Cu is embedded in the trench and the via hole to form a wiring.

However, in recent years, miniaturization of semiconductor devices has progressed more and more, and alignment accuracy is not sufficient in the photolithography technique in some cases. For this reason, instead of the photolithography technique, a method of selectively forming a film with high accuracy in a specific region on the substrate surface has been demanded.

For example, Patent Document 1 discloses a method in which, in order to selectively etch a silicon nitride (SiN) film in a substrate provided with the silicon nitride film and a silicon oxide (SiO₂) film in a plane, a hot phosphoric acid-resistant material is formed in advance as a SAM on a surface of the silicon oxide film.

Here, in order to sufficiently protect the silicon oxide film from the etching liquid, it is necessary to form a SAM excellent in denseness. However, a conventional SAM film forming method has a problem that it is difficult to form such a SAM excellent in denseness in a short time, and the production efficiency is poor.

### PRIOR ART DOCUMENT

### Patent Document

Patent Document 1: JP 5,490,071

### SUMMARY OF THE INVENTION

### Problems to be Solved by the Invention

The present invention has been made in view of the above problem, and an object thereof is to provide a substrate treating method and a substrate treating apparatus capable of efficiently forming a self-assembled monolayer excellent in denseness and protection performance on a substrate surface in a short time by suppressing or reducing occurrence of film defects.

### Solutions to the Problems

In order to solve the above problem, a substrate treating method according to the present invention is a substrate treating method for forming a self-assembled monolayer on a surface of a substrate, the substrate treating method comprising, a first contact step of bringing a first treating liquid containing molecules capable of forming the self-assembled monolayer into contact with the surface to chemically adsorb the molecules; a removal step of removing the molecules not chemically adsorbing on the surface of the substrate; a surface modification step of performing surface modification on a region of the surface where the molecule does not exist after the removal step to a region where chemical adsorption of the molecules is possible; and a second contact step of bringing a second treating liquid containing the molecules and having a same type as or different type from the first treating liquid into contact with the region to which the surface modification has been performed to chemically adsorb the molecules.

With the above configuration, in a first contact step, a molecule (hereinafter, may be referred to as the “SAM molecule”) capable of forming the self-assembled monolayer (hereinafter, may be referred to as “SAM”) is chemically adsorbed on the surface of the substrate, and then, in a removal step, the non-chemically adsorbed SAM molecule is removed. Thus, it is possible to suppress the inhibition of the surface modification on a region where the SAM molecule could not be chemically adsorbed. Further, the surface modification is performed on a region where the SAM molecule can be chemically adsorbed in a surface modification step, and the SAM molecule is chemically adsorbed in a region where the surface modification has been performed in a second contact step. As described above, with the above configuration, the region where the SAM molecule could not be chemically adsorbed in the first contact step is subjected to the surface modification so that the SAM molecule can be chemically adsorbed, and then the SAM molecule is chemically adsorbed again, and therefore, it is possible to reduce the contact of the SAM molecule on the substrate surface for a long time in order to form a dense SAM as in the conventional substrate treating method. As a result, occurrence of film defects can be suppressed, and a SAM excellent in denseness and protection performance can be efficiently formed in a short time.

According to the above configuration, the first contact step can be a step of bringing the first treating liquid into contact with the surface of the substrate to chemically adsorb the molecules in a region where chemical adsorption is possible to self-assemble the molecules to form the self-assembled monolayer, and the second contact step can be a step of performing a densification treatment on the self-assembled monolayer by chemically adsorbing the molecules to the region to which the surface modification has been performed in the surface modification step.

With the above configuration, after the SAM is formed in the first contact step, the SAM molecule not chemically adsorbed on the surface of the substrate is removed in the removal step, and further, the surface modification is performed so that the SAM molecule can be chemically adsorbed in the region where the SAM molecule does not exist. Thereafter, in the second contact step, a second treating liquid containing the SAM molecule is brought into contact with the region where the SAM molecule does not exist. Here, in the SAM formed in the first contact step, there is a case where a film defect occurs because the SAM molecule cannot be chemically adsorbed locally on the surface of the substrate. However, with the above configuration, after the formation of the SAM in the first contact step, the surface modification is performed after the non-chemically adsorbed SAM molecule is removed from the region where the film defect occurs, and the SAM molecule is chemically adsorbed to the region where the film defect occurs, so that the denseness of the SAM can be increased or improved. As a result, unlike the conventional SAM film forming method, it is not necessary to bring the SAM molecule into contact with the substrate surface for a long time, and a SAM excellent in denseness and protection performance can be efficiently formed in a short time.

According to the above configuration, the substrate may have at least the surface made of silicon dioxide, the molecule may have a functional group capable of forming a siloxane bond with a hydroxyl group, the surface modification in the surface modification step may generate a hydroxyl group in a region where the molecule does not exist, and the chemical adsorption of the molecule in the first contact step and the second contact step may bond the molecule to the surface through the siloxane bond with the hydroxyl group on the surface of the substrate.

With the above configuration, by performing surface modification on a substrate having at least a surface formed of silicon dioxide such that a hydroxyl group is generated on the surface, a molecule having a functional group capable of forming a siloxane bond with the hydroxyl group can be chemically adsorbed on the substrate surface via the siloxane bond.

According to the above configuration, the surface modification step may be a step of bringing a surface modification liquid into contact with a region of the surface where the molecule does not exist after the removal step, and a solution for generating the hydroxyl group on the surface made of the silicon dioxide may be used as the surface modification liquid.

According to the above configuration, the surface modification step may be at least one of a step of bringing ozone gas into contact with a region of the surface where the molecule does not exist, a step of irradiating a region of the surface where the molecule does not exist with ultraviolet rays, and a step of bringing a gas containing moisture into contact with a region of the surface where the molecule does not exist.

According to the above configuration, it is preferable that the molecule includes octadecyltrichlorosilane.

In order to solve the above problem, a substrate treating apparatus of the present invention is a substrate treating apparatus for forming a self-assembled monolayer on a surface of a substrate, the substrate treating apparatus comprising, a supply portion that supplies a treating liquid containing molecules capable of forming the self-assembled monolayer to the surface; a removal liquid supply portion that supplies a removal liquid to the surface after supply of the treating liquid to remove the molecules not chemically adsorbing; and a surface modification portion that performs surface modification on a region where the molecule does not exist, the region being the surface after removal of the molecule by the removal liquid supply portion, to a region where chemical adsorption of the molecules is possible, wherein the supply portion also supplies the treating liquid to the surface of the substrate after the surface modification by the surface modification portion.

With the above configuration, a supply portion can supply the treating liquid containing the SAM molecule to the surface of the substrate, thereby chemically adsorbing it to the region where the chemical adsorption of the SAM molecule is possible. In addition, a removal liquid supply portion can sufficiently expose the region where the SAM molecule is not chemically adsorbed by removing the SAM molecule not chemically adsorbed on the surface of the substrate. Further, a surface modification portion performs surface modification on the region where the SAM molecule is not chemically adsorbed, thereby enabling chemical adsorption of the SAM molecule to the region. That is, with the above configuration, it is possible to provide the substrate treating apparatus capable of efficiently forming the SAM excellent in denseness and protection performance in a short time as compared with the conventional substrate treating apparatus by supplying the treating liquid to the region where the surface modification has been performed again by the supply portion so that the SAM molecule can also be chemically adsorbed to the region.

With the above configuration, the substrate may have at least the surface made of silicon dioxide, the molecule may have a functional group capable of forming a siloxane bond with a hydroxyl group, the surface modification portion may be a surface modification liquid supply portion that supplies a surface modification liquid to a region where the molecule does not exist, and a solution for generating the hydroxyl group on the surface made of the silicon dioxide may be used as the surface modification liquid.

With the above configuration, the substrate has at least the surface made of silicon dioxide, the molecule has a functional group capable of forming a siloxane bond with a hydroxyl group, and the surface modification portion may be at least one of an ozone gas supply portion that supplies ozone gas to a region of the surface where the molecule does not exist, an ultraviolet irradiation portion that irradiates a region of the surface where the molecule does not exist with ultraviolet rays, and a gas supply portion that supplies a gas containing moisture to a region of the surface where the molecule does not exist.

### Effects of the Invention

According to the present invention, it is possible to provide a substrate treating method and a substrate treating apparatus capable of efficiently forming a self-assembled monolayer having high film density, excellent denseness, favorably suppressed or reduced occurrence of film defects, and excellent protection performance on a substrate surface in a shorter time than in a conventional film forming method.

### BRIEF DESCRIPTION OF THE DRAWINGS

FIG. 1 is a flowchart illustrating an example of an overall flow of a substrate treating method according to a first embodiment of the present invention.

FIG. 2A is a schematic diagram illustrating a state in which a first treating liquid is supplied to a substrate surface in the first embodiment.

FIG. 2B is a schematic diagram illustrating a state in which SAM molecules are chemically adsorbed on a substrate surface in the first embodiment.

FIG. 2C is a schematic diagram illustrating a state in which the SAM molecules are self-assembled on the substrate surface to form a SAM in the first embodiment.

FIG. 3A is a schematic diagram illustrating a state of the substrate surface after non-adsorbed SAM molecules and reverse micelles are removed in the first embodiment.

FIG. 3B is a schematic diagram illustrating a state in which surface modification is performed on a region where no SAM molecule exists to generate a hydroxyl group in the first embodiment.

FIG. 3C is a schematic diagram illustrating a state in which the SAM is densified in the first embodiment.

FIG. 4 is an explanatory diagram illustrating a schematic configuration of a substrate treating apparatus according to the first embodiment of the present invention.

FIG. 5 is an explanatory diagram illustrating a schematic configuration of a treating liquid storage portion provided in a supply portion in the substrate treating apparatus according to the first embodiment of the present invention.

FIG. 6 is an explanatory diagram illustrating a schematic configuration of another treating liquid storage portion provided in the supply portion in the substrate treating apparatus according to the first embodiment of the present invention.

FIG. 7 is an explanatory diagram illustrating a schematic configuration of a removal liquid storage portion provided in a removal liquid supply portion in the substrate treating apparatus according to the first embodiment of the present invention.

FIG. 8 is an explanatory diagram illustrating a schematic configuration of a surface modification liquid storage portion provided in a surface modification liquid supply portion in the substrate treating apparatus according to the first embodiment of the present invention.

FIG. 9 is a flowchart illustrating an example of an overall flow of a substrate treating method according to a second embodiment of the present invention.

FIG. 10 is an explanatory diagram illustrating a schematic configuration of a substrate treating apparatus according to the second embodiment of the present invention.

FIG. 11 is a flowchart illustrating an example of an overall flow of a substrate treating method according to a third embodiment of the present invention.

FIG. 12 is an explanatory diagram illustrating a schematic configuration of a substrate treating apparatus according to the third embodiment of the present invention.

### EMBODIMENTS OF THE INVENTION

### First Embodiment

A substrate treating method and a substrate treating apparatus according to a first embodiment of the present invention will be described below.

### [Substrate Treatment Method]

First, a substrate treating method according to the present embodiment will be described below with reference to the drawings.

The substrate treating method of the present embodiment provides a technique for forming a self-assembled monolayer (hereinafter referred to as a “SAM”) that is excellent in denseness and can exhibit favorable protection performance on a surface of a substrate. Note that, in the present specification, the “substrate” refers to various substrates such as a semiconductor substrate, a glass substrate for a photomask, a glass substrate for a liquid crystal display, a glass substrate for a plasma display, a substrate for a field emission display (FED), a substrate for an optical disk, a substrate for a magnetic disk, and a substrate for a magneto-optical disk. A metal oxide is not particularly limited, but is preferably SiO₂. The substrate of the present invention may include a substrate made of only SiO₂ (SiO₂ substrate). Note that, in the following, a case where the substrate is a SiO₂ substrate will be described as an example.

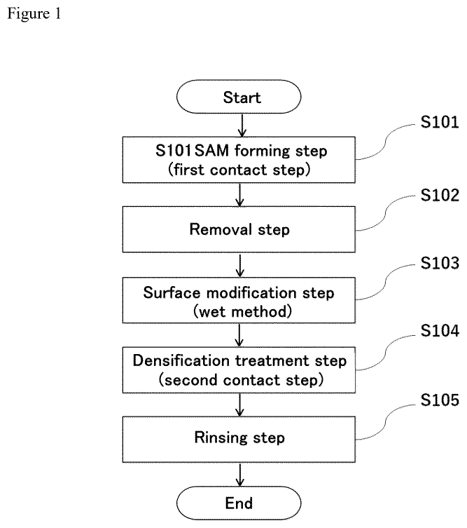

As illustrated in FIG. 1, the substrate treating method of the present embodiment includes at least a SAM forming step (first contact step) S101, a removal step S102, a surface modification step S103, a densification treatment step (second contact step) S104, and a rinsing step S105. FIG. 1 is a flowchart illustrating an example of an overall flow of a substrate treating method according to the first embodiment of the present invention.

### <SAM Forming Step (First Contact Step)>

The SAM forming step (first contact step) S101 is a step of bringing a first treating liquid containing a material (hereinafter, referred to as a “SAM forming material”) capable of forming the SAM into contact with a surface Wf of a substrate W to form the SAM.

The method of bringing the first treating liquid into contact with the substrate W is not particularly limited, and examples thereof include a method of applying the first treating liquid to the surface of the substrate W, a method of spraying the first treating liquid to the surface of the substrate W, and a method of immersing the substrate W in the first treating liquid.

Examples of the method of applying the first treating liquid to the surface of the substrate W include a method of supplying the first treating liquid to the central portion of the surface of the substrate W in a state where the substrate W is rotated at a constant speed about the central portion thereof as the axis. Thus, the first treating liquid supplied to the surface of the substrate W flows from the vicinity of the center of the surface of the substrate W toward the peripheral edge portion of the substrate W by a centrifugal force generated as a result of the rotation of the substrate W, and diffuses to the entire surface of the surface of the substrate W. As a result, the entire surface of the surface of the substrate W is covered with the first treating liquid, and a liquid film of the first treating liquid is formed.

The first treating liquid contains at least the SAM forming material. In addition, in the first treating liquid, the SAM forming material may be dissolved or dispersed in a solvent. The SAM forming material is not particularly limited, and examples thereof include organic silane compounds such as octadecyltrichlorosilane. Octadecyltrichlorosilane is a compound having a trichlorosilyl group as a functional group capable of forming a siloxane bond with a hydroxyl group. In addition, the solvent is not particularly limited, and examples thereof include ether solvents, aromatic hydrocarbon-based solvents, aliphatic hydrocarbon-based solvents, and fluorine-based solvents. The ether solvent is not particularly limited, and examples thereof include tetrahydrofuran (THF). The aromatic hydrocarbon-based solvent is not particularly limited, and examples thereof include toluene. The aliphatic hydrocarbon-based solvent is not particularly limited, and examples thereof include decane. The fluorine-based solvent is not particularly limited, and examples thereof include 1,3-bis(trifluoromethyl)benzene. These solvents can be used alone or as a mixture of two or more types. Among the exemplified solvents, from the viewpoint that octadecyltrichlorosilane can be dissolved, the aliphatic hydrocarbon-based solvent is preferable, and decane is particularly preferable.

The content of the SAM forming material is preferably in the range of 0.005 mass % to 100 mass %, more preferably in the range of 0.05 mass % to 50 mass %, and particularly preferably in the range of 1 mass % to 10 mass % with respect to the total mass of the first treating liquid.

In addition, the first treating liquid may contain a known additive as long as the effect of the present invention is not impaired. The additive is not particularly limited, and examples thereof include a stabilizer and a surfactant.

The condition for bringing the first treating liquid into contact with the substrate W is not particularly limited. However, in the SAM forming step S101 of the present embodiment, the contact time of the first treating liquid can be shortened as compared with the case of forming the SAM by the conventional method. Specifically, the time required for the SAM forming step S101 (when the substrate W is immersed in the first treating liquid, the immersion time) can be appropriately set within the range of 1 minute to 1440 minutes, preferably 1 minute to 60 minutes, and more preferably 1 minute to 10 minutes depending on the type of the SAM forming material, the concentration thereof, the type of the solvent, and the like.

Next, the process of forming the SAM will be described more specifically by taking as an example a case where the SAM forming material is octadecyltrichlorosilane.

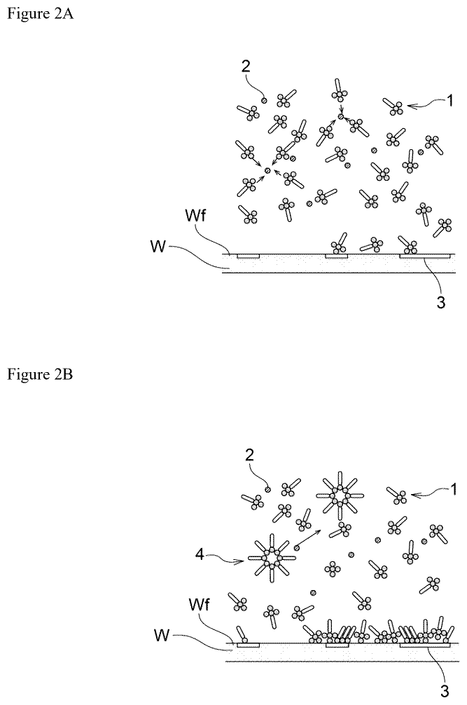

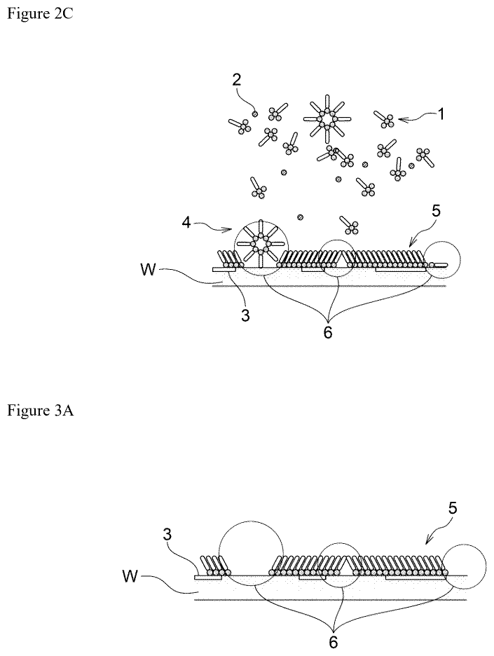

As illustrated in FIG. 2A, when the first treating liquid is supplied to the surface Wf of the substrate W, molecules (octadecyltrichlorosilane; hereinafter referred to as the “SAM molecules”) 1 capable of forming a SAM are dispersed or dissolved in the first treating liquid at the beginning of supply. FIG. 2A is a schematic diagram illustrating a state in which the first treating liquid is supplied to the surface Wf of the substrate W.

Next, as illustrated in FIG. 2B, when the hydroxyl group (OH group) 3 exists on the surface Wf of the substrate W, the SAM molecules 1 are chemically adsorbed to the surface Wf using the hydroxyl group 3 as a reaction site. More specifically, the trichlorosilyl group of the SAM molecule 1 reacts with the hydroxyl group 3 to form a siloxane bond, and thus the SAM molecule 1 is chemically adsorbed on the surface Wf. In addition, when water molecules 2 are present on the surface Wf of the substrate W or in the first treating liquid, the SAM molecules 1 aggregate around the water molecules 2. In particular, with respect to the water molecules 2 present in the first treating liquid, the SAM molecules 1 form reverse micelles 4 enclosing them therein. Note that FIG. 2B is a schematic diagram illustrating a state in which the SAM molecules 1 are chemically adsorbed on the surface Wf of the substrate W.

Subsequently, when the SAM molecules 1 are chemically adsorbed on the surface Wf of the substrate W at a high density, an island-like structure of the SAM molecules 1 appears on the surface Wf. Further, in each island, the SAM molecules 1 are self-assembled and grown (expanded) by hydrophobic interaction or electrostatic interaction between the SAM molecules 1, and finally a SAM 5 is formed (see FIG. 2C). However, in the SAM 5, a film defect 6 occurs in a region where the reverse micelles 4 adhere to the surface Wf of the substrate W, a boundary between adjacent islands where the SAM molecules 1 cannot enter, and a region where the SAM molecules 1 adhere to the surface Wf without being chemically adsorbed. Note that FIG. 2C is a schematic diagram illustrating a state in which the SAM molecules 1 are self-assembled on the surface Wf of the substrate W to form the SAM 5.

### <Removal Step>

The removal step S102 is a step of removing the first treating liquid remaining on the surface Wf of the substrate W after the SAM forming step S101. Thus, the excessive SAM molecules 1 that do not contribute to the formation of the SAM 5, more specifically, the SAM molecules 1 (including reverse micelles 4) that are not chemically adsorbed on the surface Wf of the substrate W are removed from the surface Wf of the substrate W.

The method of removing the first treating liquid from the substrate W is not particularly limited, and examples thereof include a method of applying the removal liquid to the surface Wf of the substrate W, a method of spraying the removal liquid to the surface Wf of the substrate W, and a method of immersing the substrate W in the removal liquid.

Examples of the method of applying the removal liquid to the surface Wf of the substrate W include a method of supplying the removal liquid to the central portion of the surface Wf of the substrate W in a state where the substrate W is rotated at a constant speed about the central portion thereof as the axis. Thus, the removal liquid supplied to the surface Wf of the substrate W flows from the vicinity of the center of the surface Wf of the substrate W toward the peripheral edge portion of the substrate W by a centrifugal force generated as a result of the rotation of the substrate W, and diffuses to the entire surface of the surface Wf of the substrate W. As a result, the first treating liquid on the surface Wf of the substrate W is replaced with the removal liquid, the entire surface of the surface Wf of the substrate W is covered with the removal liquid, and a liquid film of the removal liquid is formed.

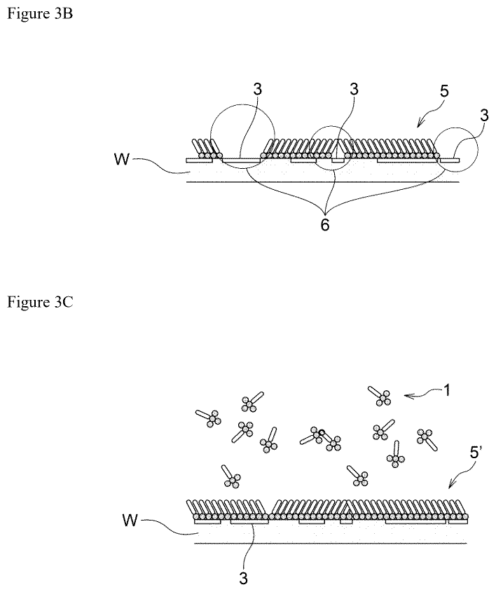

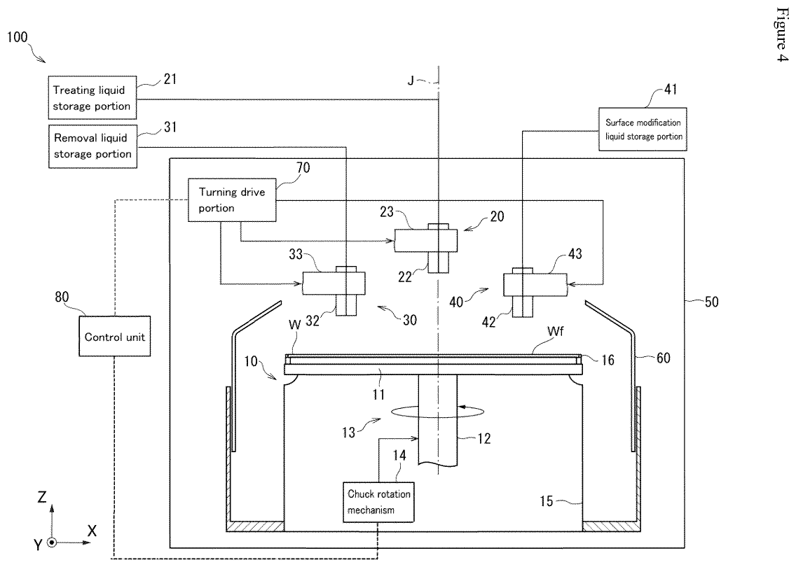

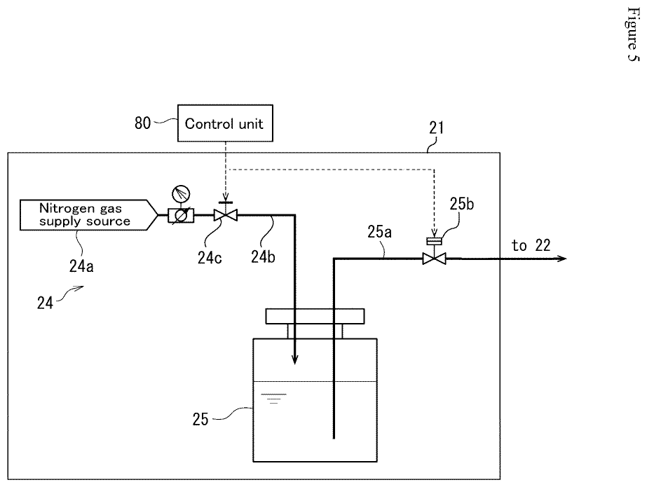

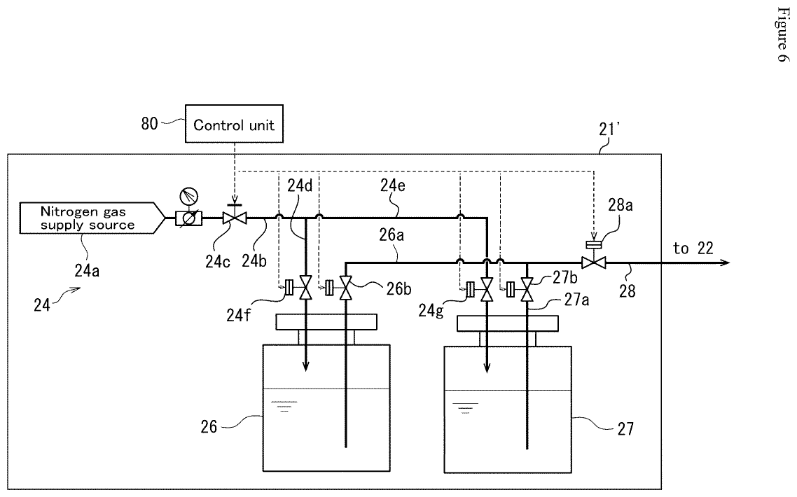

When the SAM forming material is octadecyltrichlorosilane, the surface Wf of the substrate W after the removal step S102 is as illustrated in FIG. 3A. As illustrated in the figure, the SAM molecules 1, the reverse micelles 4, and the like that do not contribute to the film formation of the SAM 5 are removed from the surface Wf of the substrate W. FIG. 3A is a schematic diagram illustrating a state of the surface Wf after non-adsorbed SAM molecules 1 and the reverse micelles 4 are removed.

As the removal liquid, an organic solvent in which the SAM forming material is dissolved, the solubility of water is low, and the water content is suppressed is preferable. In the case of the removal liquid capable of dissolving the SAM forming material, excessive SAM molecules 1 and reverse micelles 4 that do not contribute to the formation of the SAM 5 can be favorably removed from the surface Wf of the substrate W. The removal liquid preferably has, for example, a solubility of water at 25° C. of about 0.033% (330 ppm) or less. More specific examples of the removal liquid include toluene, decane, and 1,3-bis(trifluoromethyl)benzene. These solvents can be used alone or as a mixture of two or more types.

### <Surface Modification Step>

The surface modification step S103 is a step of performing surface modification on a region where the film defect 6 occurs on the surface Wf of the substrate W, that is, a region where the SAM 5 is not formed, to a region where chemical adsorption of the SAM molecules 1 is possible. Here, in the present specification, “performing surface modification to obtain a region where chemical adsorption is possible” means that, for example, surface modification is performed such that a hydroxyl group (OH group) is generated on the surface Wf of the substrate W. For example, when the substrate W is a SiO₂ substrate, the surface modification is a treatment of generating a silanol group (Si—OH group) on the substrate W.

When surface modification is performed on the surface Wf of the substrate W, as illustrated in FIG. 3B, in the film defect 6 of the SAM 5, the hydroxyl group 3 is generated so that the chemical adsorption of the SAM molecules 1 becomes possible. FIG. 3B is a schematic diagram illustrating a state in which surface modification is performed on a region where no SAM molecule 1 exists to generate the hydroxyl group 3.

In the present embodiment, the surface modification of the surface Wf of the substrate W is performed by a wet method. More specifically, it is performed by bringing the surface modification liquid into contact with the surface Wf of the substrate W after the removal step S102. The method of bringing the surface modification liquid into contact with the surface Wf of the substrate W is not particularly limited, and examples thereof include a method of applying the surface modification liquid to the surface Wf of the substrate W, a method of spraying the surface modification liquid to the surface Wf of the substrate W, and a method of immersing the substrate W in the surface modification liquid.

Further, examples of the method of applying the surface modification liquid to the surface Wf of the substrate W include a method of supplying the surface modification liquid to the central portion of the surface Wf of the substrate W in a state where the substrate W is rotated at a constant speed about the central portion thereof as the axis. Thus, the surface modification liquid supplied to the surface Wf of the substrate W flows from the vicinity of the center of the surface Wf of the substrate W toward the peripheral edge portion of the substrate W by a centrifugal force generated as a result of the rotation of the substrate W, and diffuses to the entire surface of the surface Wf of the substrate W. As a result, the entire surface of the surface Wf of the substrate W is covered with the surface modification liquid, and a liquid film of the surface modification liquid is formed.

Examples of the surface modification liquid include Standard Clean-1 (SC-1) (ammonia water (NH₃ concentration 28%):hydrogen peroxide water (H₂O₂ concentration 30%):DIW=1:4:20 by volume ratio), ammonium hydroxide (NH₄OH), hydrogen peroxide water (H₂O₂), ammonium fluoride (NH₄F), dilute sulfuric acid hydrogen peroxide water (SPM), dilute nitric acid, a mixed solution of hydrofluoric acid and ammonia, ozone water, ozonized deionized water, and water. Among these surface modification liquids, SC-1 is preferable from the viewpoint that a hydroxyl group can be favorably introduced into the surface Wf of the SiO₂ substrate.

Note that when the surface modification step S103 is performed by a wet method, it is preferable to sequentially perform a cleaning step for removing the surface modification liquid and a drying step immediately after the surface modification step S103. A cleaning method in the cleaning step is not particularly limited, and examples thereof include a method of supplying a cleaning liquid to the surface Wf of the substrate W and a method of immersing the substrate W in the cleaning liquid. In addition, examples of the cleaning liquid include toluene, decane, and 1,3-bis(trifluoromethyl)benzene. These solvents can be used alone or as a mixture of two or more types. Cleaning conditions such as a cleaning time and the temperature of the cleaning liquid are not particularly limited, and can be appropriately set as necessary. The drying step aims to remove the cleaning liquid remaining on the surface Wf of the substrate W. A drying method is not particularly limited, and examples thereof include a method of blowing an inert gas such as nitrogen gas onto the surface Wf of the substrate W. Drying conditions such as a drying time and the drying temperature are not particularly limited, and can be appropriately set as necessary.

### <Densification Treatment Step>

The densification treatment step (second contact step) S104 is a step of bringing the second treating liquid containing the SAM forming material into contact with the surface Wf of the substrate W after the surface modification step S103. In the region where the film defect 6 occurs, the hydroxyl group 3 is generated on the surface Wf by the surface modification step S103. Therefore, as illustrated in FIG. 3C, by bringing the second treating liquid into contact with the surface Wf of the substrate W, it is possible to chemically adsorb the SAM molecules 1 to the region where the film defect 6 occurs by a siloxane bond with the hydroxyl group 3. Thus, the film defect 6 is repaired, and as a result, a densified SAM 5′ is formed. Note that FIG. 3C is a schematic diagram illustrating a state in which the SAM 5 is densified.

The method for bringing the second treating liquid into contact with the substrate W is the same as the method for bringing the first treating liquid into contact in the SAM forming step S101 described above. Accordingly, detailed description thereof will be omitted.

The second treating liquid contains at least a SAM forming material and a solvent similarly to the first treating liquid in the SAM forming step S101. The second treating liquid may be the same type as or a different type from the first treating liquid. When the second treating liquid different from the first treating liquid is used, the content of the SAM forming material and the type of the solvent are not particularly limited. However, the SAM forming material is preferably the same as the SAM forming material of the first treating liquid.

The condition for bringing the second treating liquid into contact with the substrate W is not particularly limited. For example, the contact time (when the substrate W is immersed in the second treating liquid, the immersion time) of the second treating liquid can be appropriately set within the range of 1 minute to 1440 minutes, preferably 1 minute to 60 minutes, and more preferably 1 minute to 5 minutes depending on the type of the SAM forming material, the concentration thereof, the type of the solvent, the occurrence frequency of the film defect 6 in the plane of the SAM 5, the area of the occurrence region, and the like.

### <Rinsing Step>

The rinsing step S105 is a step of removing the second treating liquid from the surface Wf of the substrate W. Specifically, the rinsing step S105 is performed by supplying a rinsing liquid to the surface Wf of the substrate W and replacing the remaining second treating liquid with the rinsing liquid.

The method for bringing the rinsing liquid into contact with the surface Wf of the substrate W is not particularly limited, and examples thereof include a method in which the rinsing liquid is directly supplied and applied onto the substrate W, a method in which the rinsing liquid is sprayed, and a method in which the substrate W is immersed in the rinsing liquid. Examples of the method of applying the rinsing liquid to the surface Wf of the substrate W include a method of supplying the rinsing liquid to the central portion of the surface Wf of the substrate W in a state where the substrate W is rotated at a constant speed about the central portion thereof as the axis. Thus, the rinsing liquid supplied to the surface Wf of the substrate W flows from the vicinity of the center of the surface Wf of the substrate W toward the peripheral edge portion of the substrate W by a centrifugal force generated as a result of the rotation of the substrate W, and diffuses to the entire surface of the surface Wf of the substrate W. As a result, the entire surface of the surface Wf of the substrate W is covered with the rinsing liquid to form a liquid film of the rinsing liquid, and the treating liquid can be replaced with the rinsing liquid. Note that the time of the rinsing step is not particularly limited, and can be appropriately set as necessary.

Examples of the rinsing liquid include toluene, decane, and 1,3-bis(trifluoromethyl)benzene. These solvents can be used alone or as a mixture of two or more types. Rinsing conditions such as a rinsing time and the temperature of the rinsing liquid are not particularly limited, and can be appropriately set as necessary.

Immediately after the rinsing step S105, a drying step is preferably performed for the purpose of removing the rinsing liquid remaining on the surface Wf of the substrate W. A drying method is not particularly limited, and examples thereof include a method of blowing an inert gas such as nitrogen gas onto the surface Wf of the substrate W. Drying conditions such as a drying time and the drying temperature are not particularly limited, and can be appropriately set as necessary.

As described above, by the substrate treating method of the present embodiment, in order to form a dense SAM, the surface modification is performed on the region (film defect) of the substrate surface where the SAM molecules cannot be chemically adsorbed. Further, the film defect is repaired by chemically adsorbing the SAM molecules on the region where the surface modification has been performed. As a result, it is possible to form a SAM having a high film density, excellent denseness, suppressed or reduced occurrence of film defects, and excellent function as a protective film in a shorter time than the conventional method.

### [Substrate Treatment Apparatus]

Next, a substrate treating apparatus according to the present embodiment will be described below with reference to the drawings.

A substrate treating apparatus 100 of the present embodiment is a single wafer type substrate treating apparatus used for forming the SAM on the surface Wf of the substrate W, and as illustrated in FIG. 4, at least includes a substrate holding portion 10 that holds the substrate W, a supply portion 20 that supplies the first treating liquid and the second treating liquid to the surface Wf of the substrate W, a removal liquid supply portion 30 that supplies the removal liquid, a surface modification liquid supply portion (surface modification portion) 40, a chamber 50 that is a container that accommodates the substrate W, a dispersion prevention cup 60 that collects the treating liquid, a turning drive portion 70 that independently turns and drives an arm described below of each portion of the substrate treating apparatus 100, and a control unit 80 that controls each portion of the substrate treating apparatus 100. In addition, the substrate treating apparatus 100 can also include a loading/unloading means (not illustrated) that loads or unloads the substrate W. Note that FIG. 4 is an explanatory view illustrating a schematic configuration of the substrate treating apparatus according to the present embodiment. In the drawing, XYZ orthogonal coordinate axes are appropriately indicated in order to clarify the directional relationship of the illustrated object. Here, the XY plane represents a horizontal plane, and the +Z direction represents a vertically upward direction.

### <Substrate Holding Portion>

The substrate holding portion 10 is a means that holds the substrate W, and rotates the substrate W while holding the substrate W in a substantially horizontal orientation with the surface Wf of the substrate W facing upward as illustrated in FIG. 4. The substrate holding portion 10 includes a spin chuck 13 in which a spin base 11 and a rotation support shaft 12 are integrally joined. The spin base 11 has a substantially circular shape in plan view, and the hollow rotation support shaft 12 extending in a substantially vertical direction is fixed to a center portion thereof. The rotation support shaft 12 is coupled to a rotation shaft of a chuck rotation mechanism 14 including a motor. The chuck rotation mechanism 14 is accommodated in a casing 15 having a cylindrical shape, and the rotation support shaft 12 is rotatably supported by the casing 15 about the rotation axis in the vertical direction.

The chuck rotation mechanism 14 can rotate the rotation support shaft 12 about the rotation axis by driving from a chuck drive portion (not illustrated) of the control unit 80. Thus, the spin base 11 attached to an upper end portion of the rotation support shaft 12 rotates about a rotation axis J. The control unit 80 can control the chuck rotation mechanism 14 via the chuck drive portion to adjust the rotation speed of the spin base 11.

In the vicinity of the peripheral edge portion of the spin base 11, a plurality of chuck pins 16 for gripping the peripheral end portion of the substrate W is erected. The number of chuck pins 16 to be installed is not particularly limited, but it is preferable to provide at least three or more in order to unfailingly hold the substrate W having a circular shape. In the present embodiment, three chuck pins are disposed at equal intervals along the peripheral edge portion of the spin base 11. Each of the chuck pins 16 includes a substrate support pin that supports the peripheral edge portion of the substrate W from below, and a substrate holding pin that presses an outer peripheral end surface of the substrate W supported by the substrate support pin to hold the substrate W.

### <Supply Portion>

The supply portion 20 according to the present embodiment is a means that supplies the first treating liquid and the second treating liquid to the surface Wf of the substrate W. As illustrated in FIG. 4, the supply portion 20 includes a treating liquid storage portion 21, a nozzle 22, and an arm 23.

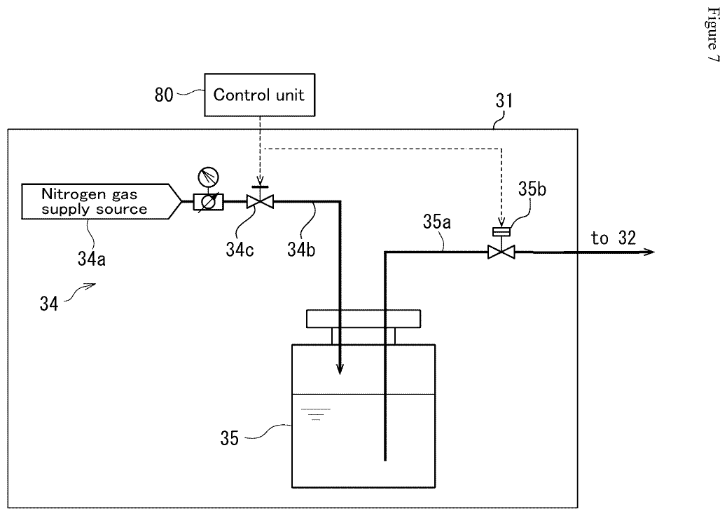

When the same type of treating liquid is used as the first treating liquid and the second treating liquid, the treating liquid storage portion 21 includes a pressurization portion 24 and a treating liquid tank 25 as illustrated in FIG. 5. Note that FIG. 5 is an explanatory diagram illustrating a schematic configuration of the treating liquid storage portion 21 in the supply portion 20.

The pressurization portion 24 includes a nitrogen gas supply source 24a as a supply source of gas for pressurizing the inside of the treating liquid tank 25, a pump (not illustrated) for pressurizing nitrogen gas, a nitrogen gas supply pipe 24b, and a valve 24c provided in the middle of the path of the nitrogen gas supply pipe 24b.

The nitrogen gas supply pipe 24b is line-connected to the treating liquid tank 25. Further, the valve 24c is provided in a middle path of the nitrogen gas supply pipe 24b. The valve 24c is electrically connected to the control unit 80, so that opening and closing of the valve 24c can be controlled according to an operation command of the control unit 80. When the valve 24c is opened according to the operation command of the control unit 80, the nitrogen gas can be supplied to the treating liquid tank 25.

The treating liquid tank 25 may include a stirring portion that stirs the treating liquid in the treating liquid tank 25 and a temperature adjustment portion that adjusts the temperature of the treating liquid (neither is illustrated). Examples of the stirring portion include a rotation portion that stirs the treating liquid and a stirring control unit that controls rotation of the rotation portion. The stirring control unit is electrically connected to the control unit 80, and the rotation portion includes, for example, a propeller-like stirring blade at the lower end of the rotation shaft. The control unit 80 gives an operation command to the stirring control unit to rotate the rotation portion, whereby the treating liquid can be stirred by the stirring blade. As a result, the concentration and temperature of the treating liquid can be made uniform in the treating liquid tank 25.

Further, a discharge pipe 25a for supplying the treating liquid to the nozzle 22 is line-connected to the treating liquid tank 25. A discharge valve 25b is provided in a middle path of the discharge pipe 25a. In addition, the discharge valve 25b is electrically connected to the control unit 80. Thus, opening and closing of the valve can be controlled according to an operation command of the control unit 80. When the discharge valve 25b is opened according to an operation command of the control unit 80, the treating liquid is pumped through the discharge pipe 25a to the nozzle 22.

The nozzle 22 is attached to the distal end portion of the arm 23 that is horizontally extended, and is disposed above the spin base 11 when the treating liquid is discharged. The arm 23 is coupled to the turning drive portion 70 via a turning shaft (not illustrated). The turning drive portion 70 is electrically connected to the control unit 80, and rotates the arm 23 according to an operation command from the control unit 80. The nozzle 22 also moves as a result of the rotation of the arm 23.

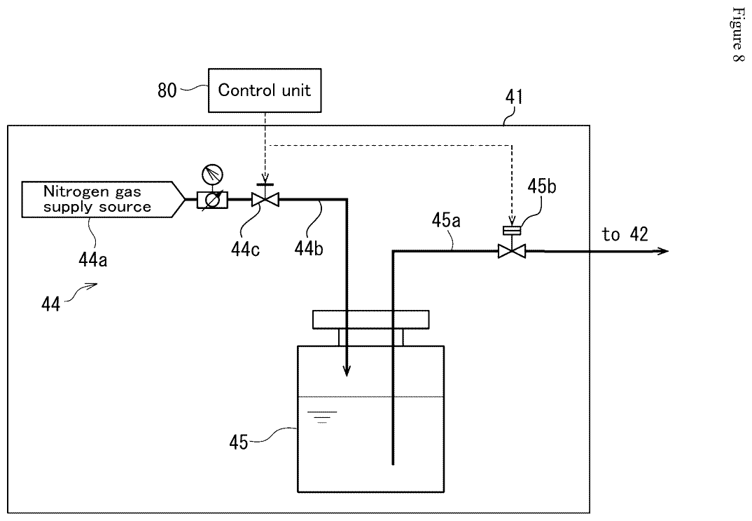

Note that when the supply portion 20 supplies different types of the first treating liquid and the second treating liquid, as illustrated in FIG. 6, a treating liquid storage portion 21′ including a pair of first treating liquid tank 26 and second treating liquid tank 27 may be used. Thus, different types of treating liquids can be used in the SAM forming step S101 and the densification treatment step S104. FIG. 6 is an explanatory diagram illustrating a schematic configuration of the treating liquid storage portion 21′ in the supply portion 20.

More specifically, the treating liquid storage portion 21′ has the configuration described below. That is, the first treating liquid tank 26 stores the first treating liquid, and the second treating liquid tank 27 stores the second treating liquid. In addition, the nitrogen gas supply pipe 24b is branched into a first nitrogen gas supply pipe 24d and a second nitrogen gas supply pipe 24e. The first nitrogen gas supply pipe 24d is line-connected to the first treating liquid tank 26, and the second nitrogen gas supply pipe 24e is line-connected to the second treating liquid tank 27. Further, a first valve 24f is provided in the middle path of the first nitrogen gas supply pipe 24d, and a second valve 24g is provided in the middle path of the second nitrogen gas supply pipe 24e. The valve 24c, the first valve 24f, and the second valve 24g are electrically connected to the control unit 80, and opening and closing of the valve 24c, the first valve 24f, and the second valve 24g can be controlled according to an operation command of the control unit 80. When the valve 24c, the first valve 24f, and the second valve 24g are opened according to the operation command of the control unit 80, the nitrogen gas can be supplied to each of the first treating liquid tank 26 and the second treating liquid tank 27.

Each of the first treating liquid tank 26 and the second treating liquid tank 27 may be provided with a stirring portion that stirs the first treating liquid in the first treating liquid tank 26 and the second treating liquid in the second treating liquid tank 27, and a temperature adjustment portion that adjusts the temperatures of the first treating liquid and the second treating liquid (neither is illustrated). Examples of the stirring portion include a rotation portion that stirs the first treating liquid or the second treating liquid and a stirring control unit that controls rotation of the rotation portion. The stirring control unit is electrically connected to the control unit 80, and the rotation portion includes, for example, a propeller-like stirring blade at the lower end of the rotation shaft. The control unit 80 gives an operation command to the stirring control unit to rotate the rotation portion, whereby the first treating liquid or the second treating liquid can be stirred by the stirring blade. As a result, the concentration and temperature of the first treating liquid and the second treating liquid can be made uniform in the first treating liquid tank 26 and the like.

Further, a first discharge pipe 26a and a second discharge pipe 27a for supplying the first treating liquid or the second treating liquid to the nozzle 22 are line-connected to the first treating liquid tank 26 and the second treating liquid tank 27, respectively. A first discharge valve 26b is provided in a middle path of the first discharge pipe 26a. In addition, a second discharge valve 27b is provided in a middle path of the second discharge pipe 27a. Further, the first discharge pipe 26a and the second discharge pipe 27a are line-connected to a third discharge pipe 28 so as to merge on the downstream side of the first discharge valve 26b and the second discharge valve 27b. A third discharge valve 28a is provided in the middle of the path of the third discharge pipe 28. In addition, the first discharge valve 26b, the second discharge valve 27b, and the third discharge valve 28a are electrically connected to the control unit 80. Thus, opening and closing of these valve can be controlled according to an operation command of the control unit 80. When the first discharge valve 26b and the third discharge valve 28a are opened according to an operation command of the control unit 80, the first treating liquid is pumped through the first discharge pipe 26a and the third discharge pipe 28 to the nozzle 22. In addition, when the second discharge valve 27b and the third discharge valve 28a are opened according to an operation command of the control unit 80, the second treating liquid is pumped through the second discharge pipe 27a and the third discharge pipe 28 to the nozzle 22.

### <Removal Liquid Supply Portion>

The removal liquid supply portion 30 according to the present embodiment is a means that supplies the removal liquid to the surface Wf of the substrate W. As illustrated in FIG. 4, the removal liquid supply portion 30 includes a removal liquid storage portion 31, a nozzle 32, and an arm 33.

As illustrated in FIG. 7, the removal liquid storage portion 31 has a function of supplying the removal liquid to the nozzle 32, and includes a pressurization portion 34 and a removal liquid tank 35. FIG. 7 is an explanatory diagram illustrating a schematic configuration of the removal liquid storage portion 31 in the removal liquid supply portion 30.

The pressurization portion 34 includes a nitrogen gas supply source 34a as a supply source of gas for pressurizing the inside of the removal liquid tank 35, a pump (not illustrated) for pressurizing nitrogen gas, a nitrogen gas supply pipe 34b, and a valve 34c provided in the middle of the path of the nitrogen gas supply pipe 34b.

A nitrogen gas supply pipe 34b is line-connected to the removal liquid tank 35. Further, a valve 34c is provided in a middle path of the nitrogen gas supply pipe 34b. The valve 34c is electrically connected to the control unit 80, so that opening and closing of the valve 34c can be controlled according to an operation command of the control unit 80. When the valve 34c is opened according to the operation command of the control unit 80, the nitrogen gas can be supplied to the removal liquid tank 35.

The removal liquid tank 35 may include a stirring portion that stirs the removal liquid in the removal liquid tank 35 and a temperature adjustment portion that adjusts the temperature of the removal liquid (neither is illustrated). Examples of the stirring portion include a rotation portion that stirs the removal liquid in the removal liquid tank 35 and a stirring control unit that controls rotation of the rotation portion. The stirring control unit is electrically connected to the control unit 80, and the rotation portion includes, for example, a propeller-like stirring blade at the lower end of the rotation shaft. The control unit 80 gives an operation command to the stirring control unit to rotate the rotation portion, whereby the removal liquid can be stirred by the stirring blade. As a result, the concentration and temperature of the removal liquid can be made uniform in the removal liquid tank 35.

Further, a discharge pipe 35a for supplying the removal liquid to the nozzle 32 is line-connected to the removal liquid tank 35. A discharge valve 35b is provided in a middle path of the discharge pipe 35a. The discharge valve 35b is electrically connected to the control unit 80. Thus, opening and closing of the discharge valve 35b can be controlled according to an operation command of the control unit 80. When the discharge valve 35b is opened according to an operation command of the control unit 80, the removal liquid is pumped through the discharge pipe 35a to the nozzle 32.

The nozzle 32 is attached to the distal end portion of the arm 33 that is horizontally extended, and is disposed above the spin base 11 when the removal liquid is discharged. The arm 33 is coupled to the turning drive portion 70 via a turning shaft (not illustrated). The turning drive portion 70 is electrically connected to the control unit 80, and rotates the arm 33 according to an operation command from the control unit 80. The nozzle 32 also moves as a result of the rotation of the arm 33.

### <Surface Modification Liquid Supply Portion>

The surface modification liquid supply portion 40 according to the present embodiment is a means that supplies the surface modification liquid to the surface Wf of the substrate W. As illustrated in FIG. 4, the surface modification liquid supply portion 40 includes a surface modification liquid storage portion 41, a nozzle 42, and an arm 43.

As illustrated in FIG. 8, the surface modification liquid storage portion 41 has a function of supplying the surface modification liquid to the nozzle 42, and includes a pressurization portion 44 and a surface modification liquid tank 45. FIG. 8 is an explanatory diagram illustrating a schematic configuration of the surface modification liquid storage portion 41 in the surface modification liquid supply portion 40.

The pressurization portion 44 includes a nitrogen gas supply source 44a as a supply source of gas for pressurizing the inside of the surface modification liquid tank 45, a pump (not illustrated) for pressurizing nitrogen gas, a nitrogen gas supply pipe 44b, and a valve 44c provided in the middle of the path of the nitrogen gas supply pipe 44b.

The nitrogen gas supply pipe 44b is line-connected to the surface modification liquid tank 45. Further, the valve 44c is provided in a middle path of the nitrogen gas supply pipe 44b. The valve 44c is electrically connected to the control unit 80, so that opening and closing of the valve 44c can be controlled according to an operation command of the control unit 80. When the valve 44c is opened according to the operation command of the control unit 80, the nitrogen gas can be supplied to the surface modification liquid tank 45.

The surface modification liquid tank 45 may include a stirring portion that stirs the surface modification liquid in the surface modification liquid tank 45 and a temperature adjustment portion that adjusts the temperature of the surface modification liquid (neither is illustrated). Examples of the stirring portion include a rotation portion that stirs the surface modification liquid in the surface modification liquid tank 45 and a stirring control unit that controls rotation of the rotation portion. The stirring control unit is electrically connected to the control unit 80, and the rotation portion includes, for example, a propeller-like stirring blade at the lower end of the rotation shaft. The control unit 80 gives an operation command to the stirring control unit to rotate the rotation portion, whereby the surface modification liquid can be stirred by the stirring blade. As a result, the concentration and temperature of the surface modification liquid can be made uniform in the surface modification liquid tank 45.

Further, a discharge pipe 45a for supplying the surface modification liquid to the nozzle 42 is line-connected to the surface modification liquid tank 45. A discharge valve 45b is provided in a middle path of the discharge pipe 45a. The discharge valve 45b is electrically connected to the control unit 80. Thus, opening and closing of the discharge valve 45b can be controlled according to an operation command of the control unit 80. When the discharge valve 45b is opened according to an operation command of the control unit 80, the surface modification liquid is pumped through the discharge pipe 45a to the nozzle 42.

The nozzle 42 is attached to the distal end portion of the arm 43 that is horizontally extended, and is disposed above the spin base 11 when the surface modification liquid is discharged. The arm 43 is coupled to the turning drive portion 70 via a turning shaft (not illustrated). The turning drive portion 70 is electrically connected to the control unit 80, and rotates the arm 43 according to an operation command from the control unit 80. The nozzle 42 also moves as a result of the rotation of the arm 43.

### <Dispersion Prevention Cup>

The dispersion prevention cup 60 is provided so as to surround the spin base 11. The dispersion prevention cup 60 is connected to a lift drive mechanism (not illustrated) and can be lifted in an up-down direction. When the first treating liquid or the like is supplied to the surface Wf of the substrate W, the dispersion prevention cup 60 is positioned at a predetermined position by the lift drive mechanism, and surrounds the substrate W held by the chuck pins 16 from a side position. Thus, the first treating liquid or the like dispersed from the substrate W or the spin base 11 can be collected.

### <Control Unit>

The control unit 80 is electrically connected to each portion of the substrate treating apparatus 100 and controls the operation of each portion. The control unit 80 includes a computer including an arithmetic processing unit and a storage unit. As the arithmetic processing unit, a CPU that performs various arithmetic processing is used. In addition, the storage unit includes ROM that is read-only memory for storing a substrate treatment program, RAM that is readable/writable memory storing various types of information, and a magnetic disk for storing control software, data, and the like. In the magnetic disk, substrate treatment conditions including supply conditions of the first treating liquid, the second treating liquid, the removal liquid, and the surface modification liquid, rinse conditions, SAM formation conditions, and the like are stored in advance. The CPU reads the substrate treatment conditions into the RAM, and controls each portion of the substrate treating apparatus 100 according to the contents.

### Second Embodiment

A substrate treating method and a substrate treating apparatus according to a second embodiment of the present invention will be described below.

The present embodiment is different from the first embodiment in that the surface modification step is performed by a dry method using ultraviolet irradiation. Even with such a configuration, a reaction site such as a hydroxyl group is formed in a region where a SAM molecule could not be chemically adsorbed, and the SAM molecule is chemically adsorbed, thereby making it possible to form a SAM excellent in denseness.

### [Substrate Treatment Method]

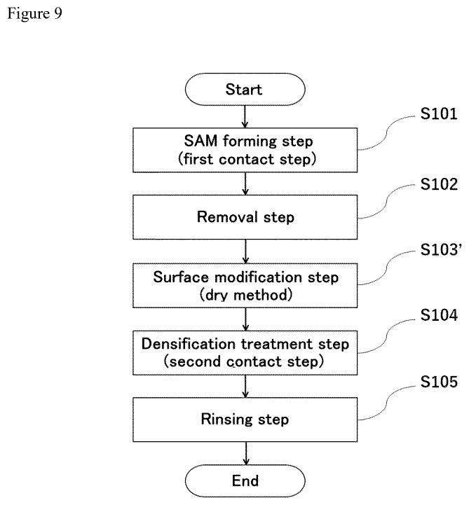

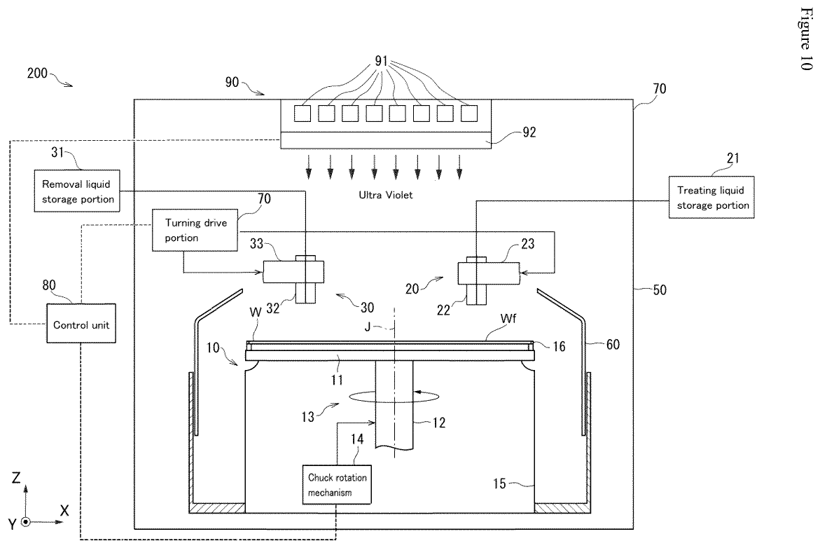

A substrate treating method according to the present embodiment will be described below with reference to FIG. 9. FIG. 9 is a flowchart illustrating an example of an overall flow of a substrate treating method according to the second embodiment of the present invention. Note that a SAM forming step S101, a removal step S102, a densification treatment step S104, and a rinsing step S105 illustrated in FIG. 9 are the same as those in the first embodiment. Accordingly, description of details of these steps will be omitted.

### 1. Surface Modification Step S103′

A surface modification step S103′ is a step of performing surface modification on a region where a film defect 6 occurs in a SAM 5, that is, a region where the SAM 5 is not formed, to a region where chemical adsorption of the SAM molecules 1 is possible.

In the present embodiment, the surface modification of a surface Wf of a substrate W is performed by a dry method using ultraviolet irradiation. In the case of ultraviolet irradiation, the irradiation conditions of ultraviolet rays such as the wavelength of a light source, irradiation intensity, and irradiation time are not particularly limited as long as a hydroxyl group 3 can be introduced to the surface Wf of the substrate W to such an extent that the SAM molecules 1 can be chemically adsorbed.

Note that, as described in the first embodiment, when the surface modification is performed by a wet method, it is preferable to perform a cleaning step for removing a surface modification liquid and a drying step. However, in the dry method using ultraviolet irradiation of the present embodiment, implementation of these steps can be omitted. Therefore, the manufacturing efficiency can be improved as compared with the substrate treating method of the first embodiment.

### [Substrate Treatment Apparatus]

Next, a substrate treating apparatus according to the present embodiment will be described below with reference to the drawings.

A substrate treating apparatus 200 according to the present embodiment is different from the substrate treating apparatus 100 of the first embodiment in that an ultraviolet irradiation portion 90 is provided in place of the surface modification liquid supply portion 40 as illustrated in FIG. 10. FIG. 10 is an explanatory view illustrating a schematic configuration of the substrate treating apparatus according to the second embodiment. Also in the drawing, XYZ orthogonal coordinate axes are appropriately indicated in order to clarify the directional relationship of the illustrated object. Here, the XY plane represents a horizontal plane, and the +Z direction represents a vertically upward direction. Note that components having functions similar to those of the substrate treating apparatus of the first embodiment are denoted by the same reference numerals, and detailed description thereof is omitted.

The ultraviolet irradiation portion 90 is disposed above the substrate holding portion 10 (in a direction indicated by an arrow Z in FIG. 10) so as to be capable of irradiating the surface Wf of the substrate W held by the substrate holding portion 10 with ultraviolet rays inside the substrate treating apparatus 200. The ultraviolet irradiation portion 90 includes at least a plurality of light source portions 91 and quartz glass 92.

The light source portions 91 illustrated in FIG. 10 are a line light source, and is disposed such that the longitudinal direction thereof is parallel to the direction indicated by Y in FIG. 10. In addition, the light source portions 91 are arranged in a direction indicated by an arrow X so as to be equally spaced from each other. However, the light source portions 91 of the present invention are not limited to this aspect. For example, ring-shaped light source portions having different diameters may be concentrically disposed as an aspect. In addition, the light source portions may be a point light source. In this case, the plurality of light source portions is preferably disposed at equal intervals in the plane.

The type of the light source portions 91 is not particularly limited, and for example, a low pressure mercury lamp, a high pressure mercury lamp, a potassium lamp, a mercury xenon lamp, a flash lamp, an excimer lamp, a metal halide lamp, an ultraviolet (UV)-light emitting diode (LED), and the like can be used. In addition, the plurality of light source portions 91 may be of the same type or different types. In a case where a plurality of light source portions 91 of different types is used, the light source portions 91 can be disposed such that peak wavelengths, light intensities, and the like are different from each other.

The quartz glass 92 is disposed between the light source portions 91 and the substrate W. The quartz glass 92 is a plate-like body and is provided so as to be parallel to the horizontal direction. In addition, the quartz glass 92 has light transmissivity, heat resistance, and corrosion resistance with respect to the ultraviolet ray, and allows the ultraviolet ray emitted from the light source portions 91 to transmit therethrough to irradiate the surface Wf of the substrate W. Further, the quartz glass 92 can protect the light source portions 91 from the atmosphere in the chamber 50.

### Third Embodiment

A substrate treating method and a substrate treating apparatus according to a third embodiment of the present invention will be described below.

The present embodiment is different from the first embodiment in that a surface modification step is performed by a dry method by supplying ozone gas or gas containing moisture. Even with such a configuration, a reaction site such as a hydroxyl group is formed in a region where a SAM molecule could not be chemically adsorbed, and the SAM molecule is chemically adsorbed, thereby making it possible to form a SAM excellent in denseness.

### [Substrate Treatment Method]

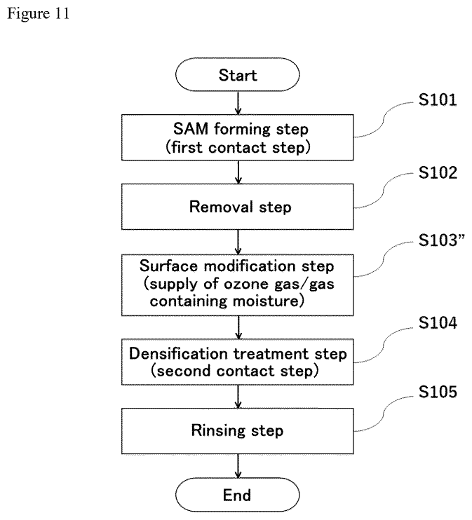

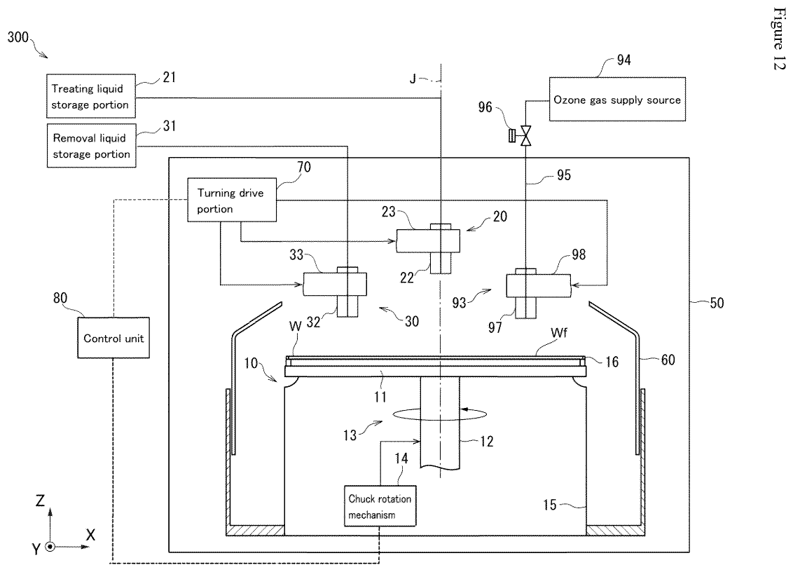

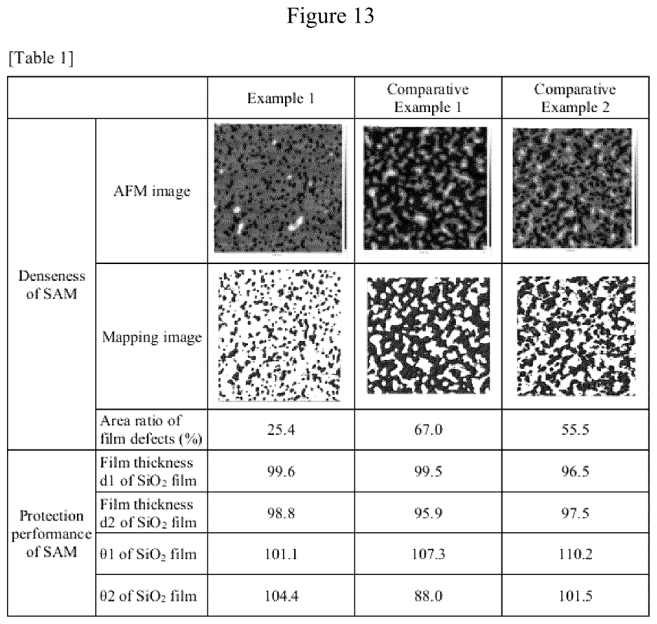

A substrate treating method according to the present embodiment will be described below with reference to FIG. 11. FIG. 11 is a flowchart illustrating an example of an overall flow of a substrate treating method according to the third embodiment of the present invention. Note that a SAM forming step S101, a removal step S102, a densification treatment step S104, and a rinsing step S105 illustrated in FIG. 11 are the same as those in the first embodiment, and thus the detailed description of these steps will be omitted.

### 1. Surface Modification Step S103″

A surface modification step S103″ is a step of performing surface modification on a region where a film defect 6 occurs in a SAM 5, that is, a region where the SAM 5 is not formed, to a region where chemical adsorption of SAM molecules 1 is possible.

In the present embodiment, the surface modification of a surface Wf of a substrate W is performed by a dry method by contact of ozone gas or gas containing moisture. In the case of the surface modification by these methods, a hydroxyl group 3 can be introduced into the surface Wf by blowing ozone gas or gas containing moisture onto the surface Wf of the substrate W or exposing the surface Wf to the atmosphere of these gases. The concentration of ozone contained in the ozone gas and the amount of moisture contained in the gas containing moisture are not particularly limited as long as the hydroxyl group 3 can be introduced to the surface Wf of the substrate W to such an extent that the SAM molecules 1 can be chemically adsorbed. In addition, contact time of ozone gas or gas containing moisture is not particularly limited as long as the hydroxyl group 3 can be introduced to the surface Wf of the substrate W to such an extent that the SAM molecules 1 can be chemically adsorbed.

### [Substrate Treatment Apparatus]

Next, a substrate treating apparatus according to the present embodiment will be described below with reference to the drawings. Note that, in the following aspect, a case where the substrate treating apparatus includes an ozone gas supply portion for supplying ozone gas will be described as an example, but a gas supply portion for supplying gas containing moisture can also adopt a similar configuration.

A substrate treating apparatus 300 according to the present embodiment is different from the substrate treating apparatus 100 of the first embodiment in that an ozone gas supply portion 93 is provided in place of the surface modification liquid supply portion 40 as illustrated in FIG. 12. Note that FIG. 12 is an explanatory view illustrating a schematic configuration of the substrate treating apparatus according to the third embodiment. Also in the drawing, XYZ orthogonal coordinate axes are appropriately indicated in order to clarify the directional relationship of the illustrated object. Here, the XY plane represents a horizontal plane, and the +Z direction represents a vertically upward direction. In addition, components having functions similar to those of the substrate treating apparatus of the first embodiment are denoted by the same reference numerals, and detailed description thereof is omitted.

The ozone gas supply portion 93 is a means that supplies ozone gas to the surface Wf of the substrate W. As illustrated in FIG. 12, the ozone gas supply portion 93 includes an ozone gas supply source 94, an ozone gas supply pipe 95, a valve 96, a nozzle 97, and an arm 98. The ozone gas supply pipe 95 supplies ozone gas from the ozone gas supply source 94 to the nozzle 97. The valve 96 is provided in a middle path of the ozone gas supply pipe 95. In addition, the valve 96 is electrically connected to a control unit 80. Thus, opening and closing of the valve 96 can be controlled according to an operation command of the control unit 80. When the valve 96 is opened according to an operation command of the control unit 80, ozone gas is pumped through the ozone gas supply pipe 95 to the nozzle 97.

The nozzle 97 is attached to the distal end portion of the arm 98 that is horizontally extended, and is disposed above a spin base 11 when the ozone gas is discharged. The arm 98 is coupled to a turning drive portion 70 via a turning shaft (not illustrated). The turning drive portion 70 is electrically connected to the control unit 80, and rotates the arm 98 according to an operation command from the control unit 80. The nozzle 97 also moves as a result of the rotation of the arm 98.

### (Other Matters)

The treating liquid supply apparatus of the present embodiment may be used in various apparatuses other than the substrate treating apparatus, or may be used alone.

### EXAMPLES

Hereinafter, preferred examples of this invention will be exemplarily described in detail. However, the materials, blending amounts, conditions, and the like described in the examples are not to limit the scope of this invention only to the materials, blending amounts, conditions, and the like unless otherwise limited.

### Example 1

A substrate having a SiO₂ film (film thickness of 100 nm) formed on a surface was prepared, and this was immersed in a hydrogen fluoride aqueous solution for one minute. As the hydrogen fluoride aqueous solution, one in which the volume ratio of hydrogen fluoride to DIW was hydrogen fluoride:DIW=1:100 was used.

Next, the substrate pulled up from the hydrogen fluoride aqueous solution was immersed in the first treating liquid containing the SAM forming material for five minutes to form a SAM (thickness of about 1 nm) on the surface of the SiO₂ film of the substrate (first contact step (SAM forming step)). As the first treating liquid, a liquid obtained by dissolving octadecyltrichlorosilane, which is a SAM forming material, in toluene, which is a solvent, was used. In addition, the content (concentration) of octadecyltrichlorosilane was 5 mass % with respect to the total mass of the first treating liquid.

Next, the removal liquid was continuously supplied to the substrate pulled up from the first treating liquid for one minute to remove the non-adsorbed SAM forming material remaining on the surface of the substrate (removal step). Decane was used as the removal liquid.

Subsequently, the substrate pulled up from the removal liquid was immersed in the surface modification liquid for one minute (surface modification step). As the surface modification liquid, SC-1 (ammonia water (NH₃ concentration 28%):hydrogen peroxide water (H₂O₂ concentration 30%):DIW=1:4:20 by volume ratio) was used. Thereafter, the substrate was pulled up from the surface modification liquid, and a nitrogen gas was blown onto the surface on which the SAM was formed to dry the substrate. The temperature of the nitrogen gas was set to normal temperature, and the drying time was set to 0.33 minutes.

Further, the dried substrate was immersed in the second treating liquid containing the SAM forming material for five minutes to form a SAM on the surface of the substrate (second contact step (densification treatment step)). As the second treating liquid, the same liquid as the first treating liquid in the first contact step was used.

Next, toluene was continuously supplied to the substrate pulled up from the second treating liquid for one minute to remove the second treating liquid (rinsing step), and then a nitrogen gas was blown onto the surface on which the SAM was formed to dry the substrate. The temperature of the nitrogen gas was set to normal temperature, and the drying time was set to 0.33 minutes. Thus, a sample according to the present example was produced.

Subsequently, the obtained sample was subjected to an etching treatment. Specifically, the substrate was immersed in the etching liquid to etch a region not protected by the SAM on the substrate surface. As etching conditions, immersion time (etching treatment time) in an etching liquid was set to 195 seconds so that the etching amount of SiO₂ was about 10 nm. In addition, as the etching liquid, a hydrogen fluoride aqueous solution was used, and the volume ratio of hydrogen fluoride to DIW was hydrogen fluoride:DIW=1:100.

Subsequently, the substrate pulled up from the etching liquid was immersed in DIW for 0.5 minutes, then the substrate was pulled up from DIW (rinsing step by DIW), and a nitrogen gas was blown onto the surface on which the etching treatment has been performed so as to dry the substrate (drying step). The temperature of the nitrogen gas was set to normal temperature, and the drying time was set to 0.33 minutes.

### Comparative Example 1

The present comparative example is different from Example 1 in that the removal step, the surface modification step, and the densification treatment step (second contact step) were not performed after the step of forming a SAM using the first treating liquid. More details are as described below.

A substrate similar to that of Example 1 was prepared, and immersed in a hydrogen fluoride aqueous solution for one minute. As the hydrogen fluoride aqueous solution, one in which the volume ratio of hydrogen fluoride to DIW was hydrogen fluoride:DIW=1:100 was used.

Next, the substrate pulled up from the hydrogen fluoride aqueous solution was immersed in the first treating liquid containing the SAM forming material for five minutes to form a SAM (thickness of about 1 nm) on the surface of the SiO₂ film of the substrate. As the first treating liquid, a liquid obtained by dissolving octadecyltrichlorosilane, which is a SAM forming material, in toluene, which is a solvent, was used. In addition, the content (concentration) of octadecyltrichlorosilane was 5 mass % with respect to the total mass of the treating liquid.

Next, toluene was continuously supplied to the substrate pulled up from the first treating liquid for one minute to remove the first treating liquid remaining on the surface of the substrate, and then a nitrogen gas was blown onto the surface on which the SAM was formed to dry the substrate. The temperature of the nitrogen gas was set to normal temperature, and the drying time was set to 0.33 minutes. Thus, a sample according to the present comparative example was produced.

Subsequently, the obtained sample was subjected to an etching treatment. Specifically, the substrate was immersed in the etching liquid to etch a region not protected by the SAM on the substrate surface. As etching conditions, immersion time (etching treatment time) in an etching liquid was set to 195 seconds so that the etching amount of SiO₂ was about 10 nm. In addition, as the etching liquid, a hydrogen fluoride aqueous solution was used, and the volume ratio of hydrogen fluoride to DIW was hydrogen fluoride:DIW=1:100.

Subsequently, the substrate pulled up from the etching liquid was immersed in DIW for 0.5 minutes, then the substrate was pulled up from DIW (rinsing step by DIW), and a nitrogen gas was blown onto the surface on which the etching treatment has been performed so as to dry the substrate (drying step). The temperature of the nitrogen gas was set to normal temperature, and the drying time was set to 0.33 minutes.

### Comparative Example 2

The present comparative example is different from Example 1 in that the surface modification step was not performed after the removal step using decane. More details are as described below.

A substrate similar to that of Example 1 was prepared, and immersed in a hydrogen fluoride aqueous solution for one minute. As the hydrogen fluoride aqueous solution, one in which the volume ratio of hydrogen fluoride to DIW was hydrogen fluoride:DIW=1:100 was used.

Next, the substrate pulled up from the hydrogen fluoride aqueous solution was immersed in the first treating liquid containing the SAM forming material for five minutes to form a SAM (thickness of about 1 nm) on the surface of the SiO₂ film of the substrate. As the first treating liquid, a liquid obtained by dissolving octadecyltrichlorosilane, which is a SAM forming material, in toluene, which is a solvent, was used. In addition, the content (concentration) of octadecyltrichlorosilane was 5 mass % with respect to the total mass of the treating liquid.

Next, the substrate pulled up from the first treating liquid was immersed in the removal liquid for one minute to remove the non-adsorbed SAM forming material remaining on the surface of the substrate. Decane was used as the removal liquid.

Subsequently, the substrate was pulled up from the removal liquid, and a nitrogen gas was blown onto the surface on which the SAM was formed to dry the substrate. The temperature of the nitrogen gas was set to normal temperature, and the drying time was set to 0.33 minutes.

Further, the dried substrate was immersed in the second treating liquid containing the SAM forming material for five minutes to form a SAM on the surface of the substrate. As the second treating liquid, the same liquid as the first treating liquid in the first contact step was used.

Next, toluene was continuously supplied to the substrate pulled up from the second treating liquid for one minute to remove the second treating liquid, and then a nitrogen gas was blown onto the surface on which the SAM was formed to dry the substrate. The temperature of the nitrogen gas was set to normal temperature, and the drying time was set to 0.33 minutes. Thus, a sample according to the present comparative example was produced.

Subsequently, the obtained sample was subjected to an etching treatment. Specifically, the substrate was immersed in the etching liquid to etch a region not protected by the SAM on the substrate (etching step). As etching conditions, immersion time (etching treatment time) in an etching liquid was set to 195 seconds so that the etching amount of SiO₂ was about 10 nm. In addition, as the etching liquid, a hydrogen fluoride aqueous solution was used, and the volume ratio of hydrogen fluoride to DIW was hydrogen fluoride:DIW=1:100.

Subsequently, the substrate pulled up from the etching liquid was immersed in DIW for 0.5 minutes, then the substrate was pulled up from DIW (rinsing step by DIW), and a nitrogen gas was blown onto the surface on which the etching treatment has been performed so as to dry the substrate (drying step). The temperature of the nitrogen gas was set to normal temperature, and the drying time was set to 0.33 minutes.

### (Evaluation of Denseness of SAM)

For each sample according to Example 1, and Comparative Examples 1 and 2, the area of the film defect of the SAM was calculated, and the denseness of the SAM was evaluated.

That is, the SAM of each sample was imaged using an atomic force microscope (AFM) (trade name: Dimension Icon, manufactured by Bruker Japan K.K.) to obtain an observation image (AFM image) of 500 nm square. Next, each of the obtained observation images was binarized, and then image processing was performed to map the film defects, thereby identifying the site (region) of the film defects of the SAM. For identification by mapping of the site (region) of the film defects of the SAM, image processing was performed so that a defect at a position of less than 1 nm in depth from the SAM surface is mapped, considering that the film thickness of the SAM is about 1 nm. Thus, the site (region) having a depth exceeding 1 nm from the SAM surface, more specifically, an etched site is mapped as a region of the film defects of the SAM, and is not included in the area. Subsequently, the area of the region of the film defects of the SAM identified by the image processing was calculated, and the ratio with respect to the area of the entire region in the observation image was calculated. The results are illustrated in Table 1.

As can be seen from Table 1, the area ratio of the film defects of the SAM in Example 1 was 25.4%, which was the smallest as compared with the area ratios of the film defects of the SAM in Comparative Example 1 and Comparative Example 2, and it was confirmed that the SAM had favorable denseness.

### (Evaluation of Protection Performance of SAM)

For each sample according to Example 1, and Comparative Examples 1 and 2, the protection performance of the SAM was evaluated based on the film thickness of the SiO₂ film and the water contact angle.

Specifically, a film thickness d1 of the SiO₂ film coated on the SAM immediately before the etching treatment and a film thickness d2 of the SiO₂ film coated on the SAM after completion of all the steps were measured using an ellipsometer (trade name: Flying MASE XI, manufactured by J. A. Woollam K.K.). The results are illustrated in Table 1.

In addition, a water contact angle θ1 of the SiO₂ film coated on the SAM immediately before the etching treatment and a water contact angle θ2 of the SiO₂ film coated on the SAM after completion of all the steps were measured using a contact angle meter (trade name: DMo-701, manufactured by Kyowa Interface Science Co., Ltd.) on the basis of the droplet method. The results are illustrated in Table 1.

As can be seen from Table 1, in Example 1, the change in the film thickness of the SiO₂ film before and after etching was 99.6 nm to 98.8 nm, and the reduction range was smaller than that in Comparative Examples 1 and 2. In addition, in Example 1, the water contact angle of the SiO₂ film surface after etching was larger than those in Comparative Examples 1 and 2. From these results, it was confirmed that the SAM of Example 1 was excellent in the protection performance for the SiO₂ film as compared with Comparative Examples 1 and 2.

### DESCRIPTION OF REFERENCE SIGNS

1: SAM molecules
2: Water molecules
3: Hydroxyl group
4: Reverse micelles
5, 5′: SAM
6: Film defect
10: Substrate holding portion
20: Supply portion
21, 21′: Treating liquid storage portion
24: Pressurization portion
25: Treating liquid tank
26: First treating liquid tank
27: Second treating liquid tank
30: Removal liquid supply portion
31: Removal liquid storage portion
35: Removal liquid tank
40: Surface modification liquid supply portion
41: Surface modification liquid storage portion
44: Pressurization portion
45: Surface modification liquid tank
80: Control unit
90: Ultraviolet irradiation portion
93: Ozone gas supply portion
100, 200, 300: Substrate treating apparatus
S101: SAM forming step (first contact step)
S102: Removal step
S103, S103′, S103″: Surface modification step
S104: Densification treatment step (second contact step)
S105: Rinsing step
W: Substrate
Wf: Surface of substrate

1. A substrate treating method for forming a self-assembled monolayer on a surface of a substrate, the substrate treating method comprising:
bringing a first treating liquid containing molecules capable of forming the self-assembled monolayer into contact with the surface to chemically adsorb the molecules;
removing the molecules not chemically adsorbing on the surface of the substrate;
performing surface modification on a region of the surface where the molecule does not exist after the removal to a region where chemical adsorption of the molecules is possible; and
bringing a second treating liquid containing the molecules and having a same type as or different type from the first treating liquid into contact with the region to which the surface modification has been performed to chemically adsorb the molecules.

2. The substrate treating method according to claim 1, wherein
the first treating liquid is brought into contact with the surface of the substrate to chemically adsorb the molecules in a region where chemical adsorption is possible to self-assemble the molecules to form the self-assembled monolayer, and
the second treatment liquid is brought into a contact with the region to which the surface modification has been performed to perform a densification treatment on the self-assembled monolayer by chemically adsorbing the molecules.

3. The substrate treating method according to claim 1, wherein
the substrate has at least the surface made of silicon dioxide,
the molecule has a functional group capable of forming a siloxane bond with a hydroxyl group,
the surface modification generates a hydroxyl group in a region where the molecule does not exist, and
the chemical adsorption of the molecule bonds the molecule to the surface through the siloxane bond with the hydroxyl group on the surface of the substrate.

4. The substrate treating method according to claim 3, wherein
the surface modification brings a surface modification liquid into contact with a region of the surface where the molecule does not exist after the removal, and
a solution for generating the hydroxyl group on the surface made of the silicon dioxide is used as the surface modification liquid.

5. The substrate treating method according to claim 3, wherein the surface modification is at least one of bringing ozone gas into contact with a region of the surface where the molecule does not exist, irradiating a region of the surface where the molecule does not exist with ultraviolet rays, and bringing a gas containing moisture into contact with a region of the surface where the molecule does not exist.

6. The substrate treating method according to claim 3, wherein the molecule includes octadecyltrichlorosilane.

7. A substrate treating apparatus for forming a self-assembled monolayer on a surface of a substrate, the substrate treating apparatus comprising:
a treatment liquid nozzle that supplies a treating liquid containing molecules capable of forming the self-assembled monolayer to the surface;
a removal liquid nozzle that supplies a removal liquid to the surface after supply of the treating liquid to remove the molecules not chemically adsorbing; and
a surface modification liquid nozzle that performs surface modification by supplying a surface modification liquid to a region where the molecule does not exist, the region being the surface after removal of the molecule by the removal liquid nozzle, to a region where chemical adsorption of the molecules is possible,
wherein the treatment liquid nozzle also supplies the treating liquid to the surface of the substrate after the surface modification.

8. The substrate treating apparatus according to claim 7, wherein
the substrate has at least the surface made of silicon dioxide,
the molecule has a functional group capable of forming a siloxane bond with a hydroxyl group, and
a solution for generating the hydroxyl group on the surface made of the silicon dioxide is used as the surface modification liquid.

9. The substrate treating apparatus according to claim 8, wherein
the substrate has at least the surface made of silicon dioxide, and
the molecule has a functional group capable of forming a siloxane bond with a hydroxyl group.

10. A substrate treatment apparatus for forming a self-assembled monolayer on a surface of a substrate, the substrate treatment apparatus comprising:
a treatment liquid nozzle that supplies a treatment liquid containing molecules capable of forming the self-assembled monolayer to the surface;
a removal liquid nozzle that supplies a removal liquid to the surface after supply of the treatment liquid to remove the molecules not chemically adsorbing; and
an ozone gas nozzle that performs surface modification by supplying ozone gas to a region where the molecule does not exist, the region being the surface after removal of the molecule by the removal liquid nozzle, to a region where chemical adsorption of the molecules is possible,
wherein the treatment liquid nozzle also supplies the treatment liquid to the surface of the substrate after the surface modification.

11. A substrate treatment apparatus for forming a self-assembled monolayer on a surface of a substrate, the substrate treatment apparatus comprising:
a treatment liquid nozzle that supplies a treatment liquid containing molecules capable of forming the self-assembled monolayer to the surface;
a removal liquid nozzle that supplies a removal liquid to the surface after supply of the treatment liquid to remove the molecules not chemically adsorbing; and
a light source that performs surface modification by irradiating a region where the molecule does not exist with ultraviolet rays, the region being the surface after removal of the molecule by the removal liquid nozzle, to a region where chemical adsorption of the molecules is possible,
wherein the treatment liquid nozzle also supplies the treatment liquid to the surface of the substrate after the surface modification.

12. A substrate treatment apparatus for forming a self-assembled monolayer on a surface of a substrate, the substrate treatment apparatus comprising:
a treatment liquid nozzle that supplies a treatment liquid containing molecules capable of forming the self-assembled monolayer to the surface;
a removal liquid nozzle that supplies a removal liquid to the surface after supply of the treatment liquid to remove the molecules that are not chemically adsorbed; and
a gas nozzle that performs surface modification by supplying a gas containing moisture to a region where the molecule does not exist, the region being the surface after removal of the molecule by the removal liquid nozzle, to a region where chemical adsorption of the molecules is possible,
wherein the treatment liquid nozzle also supplies the treatment liquid to the surface of the substrate after the surface modification.

13. The substrate treatment apparatus according to claim 11, wherein
the substrate has at least the surface made of silicon dioxide, and
the molecule has a functional group capable of forming a siloxane bond with a hydroxyl group.

14. The substrate treatment apparatus according to claim 12, wherein
the substrate has at least the surface made of silicon dioxide, and
the molecule has a functional group capable of forming a siloxane bond with a hydroxyl group.
